(19) United States
(12) Patent Application Publication
(10) Pub. No.: US 2015/0351285 A1
(43) Pub. Date: Dec. 3, 2015

(54) HEAT DISSIPATION STRUCTURE AND SYNTHESIZING METHOD THEREOF

(71) Applicants: HUAWEI TECHNOLOGIES CO., LTD., Shenzhen (CN); WASEDA UNIVERSITY, Tokyo (JP)

(72) Inventors: Suguru NODA, Tokyo (JP); Nuri NA, Tokyo (JP); Mizuhisa NIHEI, Yokohama (JP)

(21) Appl. No.: 14/612,934

(22) Filed: Feb. 3, 2015

Related U.S. Application Data
(63) Continuation of application No. PCT/CN2014/078928, filed on May 30, 2014.

(51) Int. Cl. H05K 7/20; C23C 16/26; C23C 14/34; C01B 31/02

(52) U.S. Cl. CPC H05K 7/20509; C01B 31/0226; C23C 16/26; C23C 14/34; B82Y 30/00

(57) ABSTRACT

A heat dissipation structure and a synthesizing method thereof are provided by the present disclosure. The method comprises: providing a metal foil; forming a deposition substrate on a first surface of the metal foil, wherein the deposition substrate includes a barrier layer disposed on the metal foil and a catalyst layer disposed on the barrier layer, such that catalyst in the catalyst layer is prevented from diffusing into the metal foil; and synthesizing a carbon nanotube array on the deposition substrate formed on the first surface. The method provided by the present disclosure can increase density of the CNTs in the heat dissipation structure.

### CROSS-REFERENCE TO RELATED APPLICATIONS

This application is a continuation of International Application No. PCT/CN2014/078928, filed on May 30, 2014, which is hereby incorporated by reference in its entirety.

### TECHNICAL FIELD

The present disclosure relates generally to thermal managements, and in particular, to a heat dissipation structure and a synthesizing method thereof.

### BACKGROUND

As increasing of communication data on information and communication technology (ICT), power consumption of a large-scale integrated circuit (LSI) chip is dramatically increasing with temperature, which would induce damage to the LSI chip per se. Consequently, thermal removal from a power device is becoming quite essential in ICT. A thermal interface material (TIM), which is disposed between an LSI chip and a heat spreader, is a key component for heat removal. Conventionally, a solder is used as a TIM, which has a thermal conductivity of around 50 W/(m·K). As power of an LSI chip is increasing, a TIM with better thermal conductivity is required. Carbon nanotubes (CNTs), which is highly thermal conductive, is a promising candidate of a next generation of TIM.

One example to use CNTs as a TIM is a vertically aligned CNT array. In the prior art, a five layer structure including CNT arrays grown on both sides of a metal foil is used as a CNT TIM, wherein the five layer structure is arranged as CNT array/catalyst layer/metal foil/catalyst layer/CNT array. Further information regarding the conventional CNT TIM may be found in the Applied Physics Letter, Vol. 90, 093513 (2007), herein incorporated by reference.

Thermal conductivity of CNT TIM is determined by the following parameters: thermal conductivity of CNTs per se, density of CNTs and contact resistance between materials, among which the density of CNTs is a quite important parameter. Higher density of CNTs is required to achieve higher thermal conductivity of CNT TIM. However, the inventors found that in the conventional case of the five layer structure, catalyst in the catalyst layer is easily deactivated by diffusing into the metal foil during growth process of CNTs. The CNTs cannot grow from deactivated catalyst, which in turn leads to a reduced density of CNTs.

### SUMMARY

The present disclosure provides a heat dissipation structure and a synthesizing method thereof, aiming at increasing density of the CNTs in a heat dissipation structure.

In a first aspect, a method for synthesizing a heat dissipation structure is provided, including: providing a metal foil; forming a deposition substrate on a first surface of the metal foil, wherein the deposition substrate includes a barrier layer disposed on the metal foil and a catalyst layer disposed on the barrier layer, such that catalyst in the catalyst layer is prevented from diffusing into the metal foil; and synthesizing a carbon nanotube array on the deposition substrate formed on the first surface.

In accordance with the first aspect, in a first possible implementation, the method further includes: forming the deposition substrate on a second surface of the metal foil, wherein the second surface is opposite to the first surface of the metal foil; and synthesizing a carbon nanotube array on the deposition substrate formed on the second surface.

In accordance with the first aspect or the first possible implementation of the first aspect, in a second possible implementation, the deposition substrate further includes a support layer disposed between the barrier layer and the catalyst layer, such that reactivity of the catalyst in the catalyst layer is improved.

In accordance with the first aspect or the first or second possible implementation of the first aspect, in a third possible implementation, the deposition substrate is formed by sputtering or electron beam deposition.

In accordance with any one of the first to third possible implementations of the first aspect, in a fourth possible implementation, the barrier layer in the deposition substrate has a melting temperature higher than 2000° C.

In accordance with any one of the first to fourth possible implementations of the first aspect, in a fifth possible implementation, the barrier layer in the deposition substrate contains at least one material of tantalum (Ta), nitride of tantalum and ruthenium (Ru).

In accordance with any one of the first to fifth possible implementations of the first aspect, in a sixth possible implementation, a thickness of the barrier layer in the deposition substrate ranges from 5 nm to 50 nm.

In accordance with the second possible implementation of the first aspect, in a seventh possible implementation, the support layer in the deposition substrate contains at least one material of titanium nitride (TiN) and titanium-aluminum oxynitride (Ti—Al—O—N).

In accordance with the second possible implementation of the first aspect, in an eighth possible implementation, a thickness of the support layer in the deposition substrate ranges from 5 nm to 50 nm.

In accordance with the second possible implementation of the first aspect, in a ninth possible implementation, the catalyst layer in the deposition substrate contains at least one material of iron (Fe), cobalt (Co) and nickel (Ni).

In accordance with any one of the first to ninth possible implementations of the first aspect, in a tenth possible implementation, the carbon nanotube array is synthesized by chemical vapor deposition.

In accordance with the tenth possible implementation of the first aspect, in an eleventh possible implementation, the chemical vapor deposition is performed in an atmosphere containing C2H2 at a pressure of 0.01-10 Torr, and at a temperature of 600-800° C.

In accordance with any one of the first to eleventh possible implementations of the first aspect, in a twelfth possible implementation, wherein a mass density of the carbon nanotube array ranges from 0.1 g/cm3 to 1.5 g/cm3.

In accordance with any one of the first to twelfth possible implementations of the first aspect, in a thirteenth possible implementation, wherein before the synthesizing a carbon nanotube array on the deposition substrate, the method further includes: annealing the metal foil with the deposition substrate; and the synthesizing a carbon nanotube array on the deposition substrate, includes: synthesizing a carbon nanotube array on the annealed deposition substrate.

In accordance with any one of the first to thirteenth possible implementations of the first aspect, in a fourteenth possible implementation, the method further includes: forming an adhesive layer on the carbon nanotube array.

In a second aspect, a heat dissipation structure is provided, including: a metal foil; a deposition substrate disposed on a first surface of the metal foil, wherein the deposition substrate includes a barrier layer disposed on the metal foil and a catalyst layer disposed on the barrier layer, such that catalyst in the catalyst layer is prevented from diffusing into the metal foil; and a carbon nanotube array synthesized on the deposition substrate that is disposed on the first surface.

In accordance with the second aspect, in a first possible implementation, the heat dissipation structure further includes: the deposition substrate disposed on a second surface of the metal foil, wherein the second surface is opposite to the first surface of the metal foil; and a carbon nanotube array synthesized on the deposition substrate that is disposed on the second surface.

In accordance with the second aspect or the first possible implementation of the second aspect, in a second possible implementation, the deposition substrate further includes a support layer disposed between the barrier layer and the catalyst layer, such that reactivity of the catalyst in the catalyst layer is improved.

In accordance with the second aspect or the first or second possible implementation of the second aspect, in a third possible implementation, the barrier layer in the deposition substrate has a melting temperature higher than 2000° C.

In accordance with any one of the first to third possible implementations of the second aspect, in a fourth possible implementation, the barrier layer in the deposition substrate contains at least one material of tantalum (Ta), nitride of tantalum and ruthenium (Ru).

In accordance with any one of the first to fourth possible implementations of the second aspect, in a fifth possible implementation, a thickness of the barrier layer in the deposition substrate ranges from 5 nm to 50 nm.

In accordance with the second possible implementation of the second aspect, in a sixth possible implementation, the support layer in the deposition substrate contains at least one material of titanium nitride (TiN) and titanium-aluminum oxynitride (Ti—Al—O—N).

In accordance with the second possible implementation of the second aspect, in a seventh possible implementation, a thickness of the support layer in the deposition substrate ranges from 5 nm to 50 nm.

In accordance with the second possible implementation of the second aspect, in an eighth possible implementation, the catalyst layer in the deposition substrate contains at least one material of iron (Fe), cobalt (Co) and nickel (Ni).

In accordance with any one of the first to eighth possible implementations of the second aspect, in a ninth possible implementation, a mass density of the carbon nanotube array ranges from 0.1 g/cm3 to 1.5 g/cm3.

In accordance with any one of the first to ninth possible implementations of the second aspect, in a tenth possible implementation, the heat dissipation structure further includes: an adhesive layer disposed on the carbon nanotube array.

Based on the foregoing technical solutions of the present disclosure, a carbon nanotube array is synthesized on a deposition substrate comprising a catalyst layer and a barrier layer, wherein the barrier layer is disposed between the catalyst layer and the metal foil and can prevent catalyst in the catalyst layer from diffusing into the metal foil. Consequently, density of the CNTs in the heat dissipation structure is increased and thermal conductivity of the heat dissipation structure is thus improved.

### BRIEF DESCRIPTION OF DRAWINGS

To illustrate the technical solutions in the embodiments of the present disclosure more clearly, a brief introduction on the accompanying drawings needed in the description of the embodiments is given below. Apparently, the accompanying drawings in the description below are merely some examples of the present disclosure, based on which other drawings may also be obtained by those of ordinary skill in the art without any inventive efforts.

FIG. 1 illustrates a conventional heat dissipation structure;

FIG. 2 illustrates a heat dissipation structure provided by an embodiment of the present invention;

FIG. 3 illustrates another heat dissipation structure provided by an embodiment of the present invention;

FIG. 4 illustrates another heat dissipation structure provided by an embodiment of the present invention;

FIG. 5 illustrates another heat dissipation structure provided by an embodiment of the present invention;

FIG. 6 illustrates another heat dissipation structure provided by an embodiment of the present invention;

FIG. 7 illustrates an exemplary application scenario of the heat dissipation structure illustrated by FIG. 5;

FIG. 8 illustrates a method for synthesizing a heat dissipation structure provided by an embodiment of the present invention;

FIG. 9 illustrates another method for synthesizing a heat dissipation structure provided by an embodiment of the present invention;

FIG. 10 illustrates another method for synthesizing a heat dissipation structure provided by an embodiment of the present invention; and

FIG. 11 is a cross-sectional view of a heat dissipation structure synthesized by the method illustrated by FIG. 9.

### DESCRIPTION OF EMBODIMENTS

Hereinafter, a clear and complete description of technical solutions of the embodiments of the present invention will be given below, in combination with the accompanying drawings in the embodiments of the present disclosure. Apparently, the embodiments described below are merely a part, but not all, of the embodiments of the present disclosure. All of other embodiments, obtained by those skilled in the art based on the embodiments of the present invention without any inventive efforts, fall into the protection scope of the present disclosure.

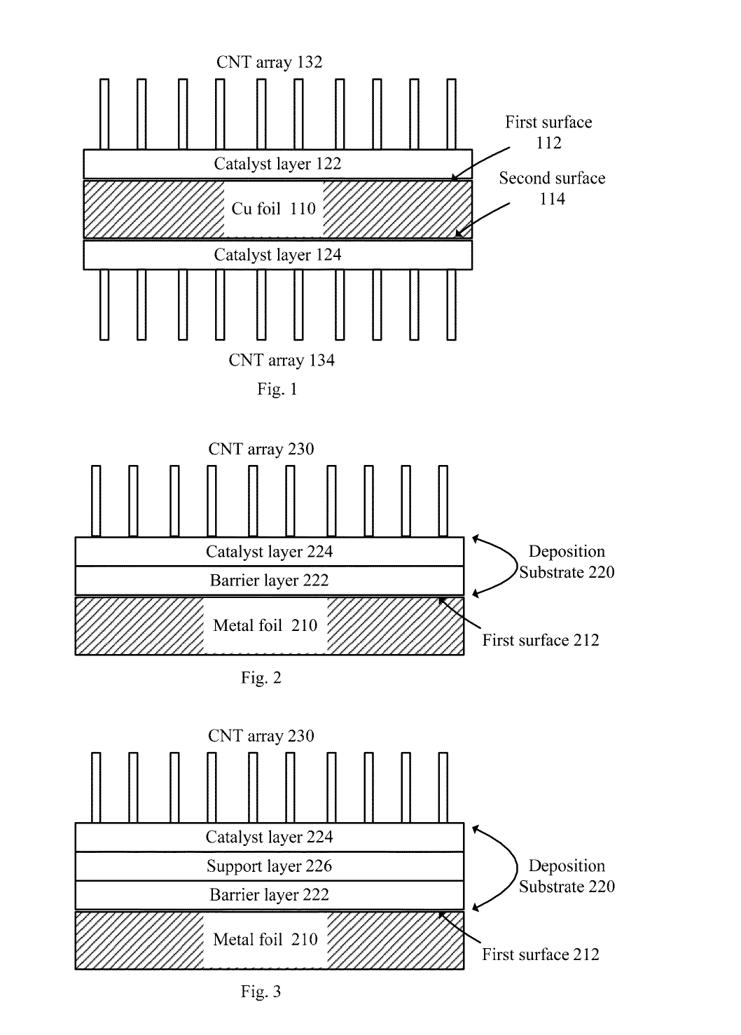

FIG. 1 illustrates an arrangement of a conventional heat dissipation structure 100 that is reported in the Applied Physics Letter, Vol. 90, 093513 (2007). Referring to FIG. 1, the heat dissipation structure 100 includes:

a Cu foil 110, wherein the metal foil 110 has two opposite surfaces 112 and 114;

two catalyst layers 122 and 124 disposed on the surface 112 and the surface 114 respectively; and

two CNT arrays 132 and 134 deposited on the two catalyst layers 122 and 124 respectively.

In the heat dissipation structure 100, a thickness of the Cu foil 110 is 10 μm, and each of the catalyst layers 122 and 124 has a trilayer configuration, i.e., a 3 nm Fe layer on a 10 nm Al layer on a 30 nm Ti layer. The CNT arrays 132 and 134 are synthesized by using plasma enhanced chemical vapor deposition (PECVD). Gases used in the PECVD process are H2 and CH4, and growth pressure and temperature are 10 Torr and 900° C. respectively. At such a high temperature, the catalyst nanoparticles in the catalyst layers 122 and 124 have a quite large potential to diffuse into the Cu foil 110. Since CNT cannot be deposited on a place without catalyst nanoparticles, deactivation of the catalyst layer results in a low density of CNTs in the heat dissipation structure (around 0.01 g/cm3˜0.06 g/cm3).

The present invention provides a heat dissipation structure and a method for synthesizing the heat dissipation structure, aiming at increasing density of the CNTs in a heat dissipation structure.

It should be recognized that, in the present disclosure, a heat dissipation structure may refer to any apparatus or unit that is thermal conductive, such as a die, a device, a module or a combination of several dies, devices, modules or even a heat spreader that dissipates heat to a heat sink or the like, and no limitation is set on specific implementation of the heat dissipation structure.

Referring to FIG. 2, a heat dissipation structure 200 is provided by an embodiment of the present invention. The heat dissipation structure 200 includes: a metal foil 210, a deposition substrate 220 disposed on a first surface 212 of the metal foil 210 and a carbon nanotube array 230 synthesized on the deposition substrate 220 that is disposed on the first surface 212.

The metal foil 210 has two opposite surfaces, i.e., a first surface 212 and a second surface 214, and may have a thickness from 10 μm to 100 μm. The metal foil 210 may be composed of any suitable material with high thermal conductivity. For instance, the metal foil 210 may be composed of a metal such as Cu, Al or the like, or of a metal alloy, such as aluminum alloy, copper alloy or the like, or of a metal oxide or any combination thereof The present invention does not set limitation to specific implementation of the metal foil.

The deposition substrate 220 comprises a barrier layer 222 and a catalyst layer 224 disposed on the barrier layer 222. In this case, when the deposition substrate 220 is disposed on the first surface 212 of the metal foil 210, the barrier layer 222 is disposed between the catalyst layer 224 and the first surface 212 of the metal foil 210. In addition, the barrier layer 222 is composed of material with a relatively high melting temperature and thus can prevent the catalyst layer 224 from diffusing into the metal foil 210.

The carbon nanotube (CNT) array 230 is synthesized on the catalyst layer 224 of the deposition substrate 220. Optionally, the CNT array 230 may includes uniformly distributed CNTs or CNT bundles. The CNTs in the CNT array 230 may be multi-walled or single-walled, and may be vertically aligned. Lengths and diameters of the CNTs in the CNT array 230 may be optimized by adjusting parameters in a process for synthesizing the CNT array 230, for instance, a CNT in the CNT array 230 may have a diameter from 5 nm to 20 nm and a length from 20 μm to 100 μm, but no limitation is set herein.

The CNT array 230 may be synthesized by chemical vapor deposition (CVD), such as thermal CVD, PECVD, hot-wire CVD (HWCVD) or the like, or by any other suitable method. The present invention does not set limitation to a specific method for synthesizing the CNT array and specific form of the CNT array.

According to the heat dissipation structure provided by the present invention, a carbon nanotube array is synthesized on a deposition substrate comprising a catalyst layer and a barrier layer, wherein the barrier layer is disposed between the catalyst layer and the metal foil and can prevent catalyst in the catalyst layer from diffusing into the metal foil. As a result, density of the CNTs in the heat dissipation structure is increased and thermal conductivity of the heat dissipation structure is thus improved.

Optionally, the catalyst layer 224 in the deposition substrate 220 contains at least one material of iron (Fe), cobalt (Co) and nickel (Ni). As an alternative, the catalyst layer 224 may also contain an alloy of any combination of the above-mentioned elements, or contain at least one of Al, Ti and Mo as a co-catalyst. The present invention does not set limitation to composition of the catalyst layer.

The catalyst layer 224 in the deposition substrate 220 may has a monolayer configuration or a multilayer configuration. For instance, the catalyst layer 224 has a multilayer configuration of Fe/Al, Fe/Co, Fe/Co/Al, etc.

In some aspects of the present invention, the barrier layer 222 in the deposition substrate 220 has a melting temperature higher than 2000° C.

In some aspects of the present invention, the barrier layer 222 in the deposition substrate 220 contains at least one material of tantalum (Ta), nitride of tantalum and ruthenium (Ru).

The nitride of tantalum may be TaNx, where 0<x≦1. The barrier layer 222 may also contain other material and the present invention does not set limitation to composition of the barrier layer.

Optionally, a thickness of the barrier layer 222 in the deposition substrate 220 may range from 5 nm to 50 nm, but the thickness of the barrier layer 222 may also be other values and no limitation is set herein.

In some aspects of the present invention, as shown in FIG. 3, the deposition substrate 220 further includes a support layer 226 disposed between the barrier layer 222 and the catalyst layer 224, such that reactivity of the catalyst in the catalyst layer 224 is improved.

The support layer 226 may have a moderate interaction with the catalyst layer 224, such that the catalyst in the heat dissipation structure is neither in a state of a continuous film nor in a state of sparsely distributed large particles, but in a state of densely distributed small particles. Therefore, reactivity of the catalyst nanoparticles in the catalyst layer 224 can be improved. In the present invention, the support layer 226 may include any suitable material capable of improving reactivity of the catalyst in the catalyst layer 224, so as to further increase the density of the CNTs in the synthesized heat dissipation structure.

In some aspects of the present invention, the support layer 226 in the deposition substrate 220 contains at least one material of titanium nitride (TiN) and titanium-aluminum oxynitride (Ti—Al—O—N). In the titanium-aluminum oxynitride, ratios of the components can be adjusted according to practical requirements. For instance, ratios of the elements in the titanium-aluminum oxynitride are all zero except for titanium, and in this case, the support layer 226 is composed of titanium. Generally, the titanium-aluminum oxynitride may have a relatively high melting temperature and is thermally conductive, but no limitation is set herein. The present invention does not set limitation to a composition of the support layer 226.

In some aspects of the present invention, a thickness of the support layer 226 in the deposition substrate 220 ranges from 5 nm to 50 nm, but the thickness of the support layer 226 may also be other values and no limitation is set herein.

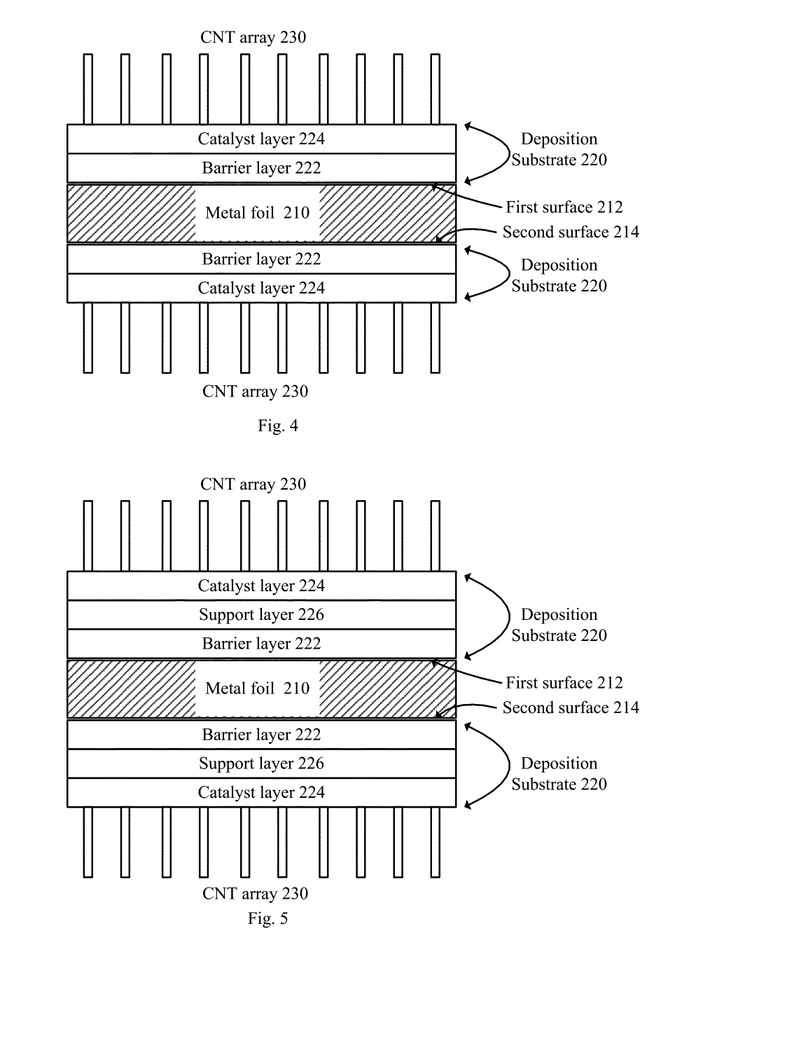

In some aspects of the present invention, the heat dissipation structure 200 may have a symmetric arrangement on the first surface and the second surface. Accordingly, referring to FIG. 4 and FIG. 5, the heat dissipation structure 200 further includes:

the deposition substrate 220 disposed on a second surface 214 of the metal foil 210, wherein the second surface 214 is opposite to the first surface 212 of the metal foil 210; and

a carbon nanotube array 230 synthesized on the deposition substrate 220 that is disposed on the second surface 214.

In this case, a total length of the heat dissipation structure 200 may range from 100 μm to 150 μm. The heat dissipation structure may have a symmetric configuration on the first surface 212 and the second surface 214, and accordingly, the deposition structure disposed on the second surface 214 may have a same configuration with that disposed on the first surface 212, i.e., deposition structure disposed on the second surface 214 may include a barrier layer and a catalyst layer disposed on the barrier layer, or further with a support layer in between.

Likely, the CNT array 230 synthesized on the deposition substrate 220 disposed on the second surface 214 may have a similar arrangement with that synthesized on the deposition substrate 220 that is disposed on the first surface 212, and will not be described in detail herein. Optionally, a mass density of the carbon nanotube array 230 ranges from 0.1 g/cm3 to 1.5 g/cm3.

It should be recognized that, in the present disclosure, when the heat dissipation structure 200 includes the deposition substrate 220 configuration only on one surface of the first surface and the second surface, term “deposition substrate” refers to only the deposition substrate 220 included by the heat dissipation structure; and when the heat dissipation structure 200 includes the deposition substrate 220 configuration on both the first surface and the second surface, otherwise specified in the context, the term “deposition substrate” refers to the deposition substrate 220 disposed on both the second surface 214 and the first surface 212. So as terms “barrier layer”, “support layer”, “catalyst layer” and “CNT array”.

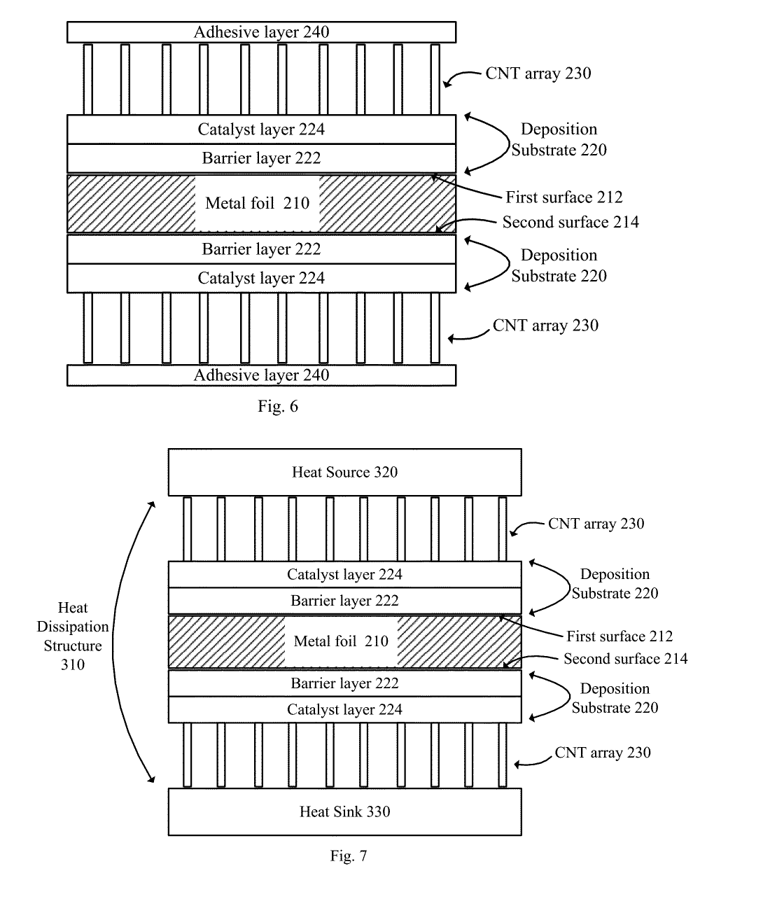

As shown in FIG. 6, in some aspects of the present invention, the heat dissipation structure 200 further includes: an adhesive layer 240 disposed on the carbon nanotube array 230.

The adhesive layer is disposed on the carbon nanotube array so as to achieve good thermal and electrical contact. The adhesive layer 240 may be prepared as a metal sheet and has a thickness from 10 μm to 20 μm. As an alternative, solder may be served as the adhesive layer 240, but no limitation is set herein.

As an alternative, the heat dissipation structure 200 may have a different arrangement on the first surface with that on the second surface of the metal foil. For instance, only one of the deposition substrate 220 disposed on the first surface and the deposition substrate 220 disposed on the second surface includes a support layer, or at least one of the barrier layer and the catalyst layer in the deposition substrate 220 disposed on the second surface has a different composition or configuration with that on the first surface, or the like. No limitation is set herein.

According to the heat dissipation structure provided by the present disclosure, a carbon nanotube array is synthesized on a deposition substrate comprising a catalyst layer and a barrier layer, wherein the barrier layer is disposed between the catalyst layer and the metal foil and can prevent catalyst in the catalyst layer from diffusing into the metal foil. As a result, density of the CNTs in the heat dissipation structure is increased and thermal conductivity of the heat dissipation structure is thus improved.

FIG. 7 illustrates an exemplary application scenario of the heat dissipation structure 200. Referring to FIG. 7, a heat dissipation system 300 includes a heat dissipation structure 310, a heat source 320 and a heat sink 330, wherein the heat dissipation structure 310 is disposed between the heat source 320 and the heat sink 330, and is thermally coupled to both the heat source 320 and the heat sink 330.

FIG. 7 takes the heat dissipation structure 200 illustrated by FIG. 4 as an example, but the heat dissipation structure 310 may be the heat dissipation structure 200 illustrated by any one of FIG. 2 to FIG. 6.

The heat source 320 may be a structure that generates heat when operating or only a body with higher temperature, such as a device in PCB or the like, and no limitation is set herein by the present invention.

An introduction on a method for synthesizing a heat dissipation structure provided by the present invention is given below. Now referring to FIG. 8, execution flow of a method 400 for synthesizing a heat dissipation structure is depicted.

S410, a metal foil is provided.

The metal foil may be composed of any suitable material with high thermal conductivity. For instance, the metal foil may be composed of a metal such as Cu, Al or the like, or of a metal alloy, such as aluminum alloy, copper alloy or the like, or of a metal oxide or any combination thereof No limitation is set to specific implementation of the metal foil in the present disclosure.

S420, a deposition substrate is formed on a first surface of the metal foil, wherein the deposition substrate comprises a barrier layer disposed on the metal foil and a catalyst layer disposed on the barrier layer, such that catalyst in the catalyst layer is prevented from diffusing into the metal foil.

The barrier layer in the deposition substrate is disposed on the first surface of the metal foil, and the catalyst layer in the deposition substrate is disposed on the barrier layer of the deposition substrate. In this case, the barrier layer is disposed between the catalyst layer and the first surface of the metal foil. In addition, the barrier layer is composed of material that has a relatively high melting temperature and thus can prevent the catalyst layer from diffusing into the metal foil.

S430, synthesizing a carbon nanotube array on the deposition substrate formed on the first surface.

The carbon nanotube (CNT) array may be synthesized by chemical vapor deposition (CVD), such as thermal CVD, PECVD, hot-wire CVD (HWCVD) or the like, or by any other suitable method. The present invention does not set limitation to a specific method for synthesizing the CNT array.

According to the method for synthesizing the heat dissipation structure, a carbon nanotube array is synthesized on a deposition substrate comprising a catalyst layer and a barrier layer, wherein the barrier layer is disposed between the catalyst layer and the metal foil and can prevent catalyst in the catalyst layer from diffusing into the metal foil. Consequently, density of the CNTs in the heat dissipation structure is increased and thermal conductivity of the heat dissipation structure is thus improved.

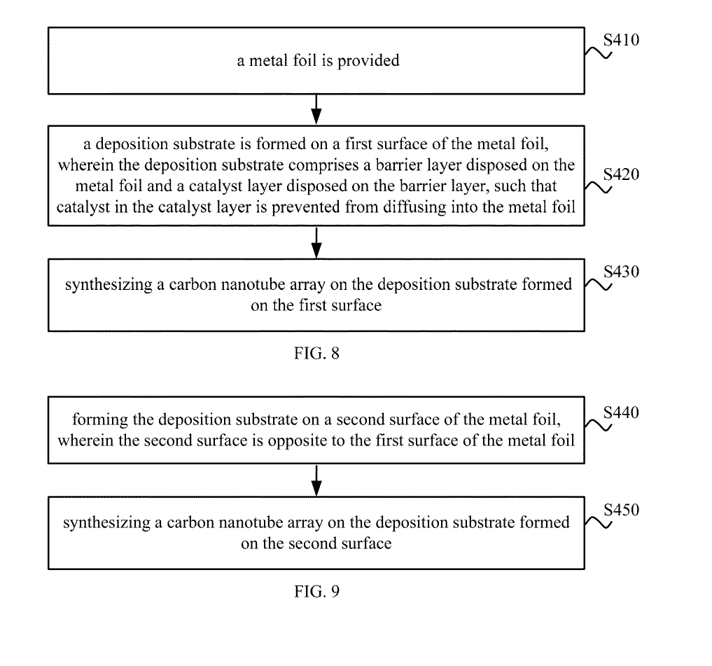

Optionally, as shown in FIG. 9, the method 400 further comprises:

S440, forming the deposition substrate on a second surface of the metal foil, wherein the second surface is opposite to the first surface of the metal foil; and

S450, synthesizing a carbon nanotube array on the deposition substrate formed on the second surface.

In the method 400, the deposition substrate on the second surface may be formed by employing a same method as that on the first surface, and accordingly, the deposition substrate formed on the second surface may have a same configuration as that formed on the first surface; furthermore, S440 may be executed concurrently with S420, and S450 may be executed concurrently with S430, such that the CNT arrays are synthesized on both sides of the metal foil at a same time, but no limitation is set herein.

As an alternative, the deposition substrate further includes a support layer disposed between the barrier layer and the catalyst layer, such that reactivity of the catalyst in the catalyst layer is improved.

If the deposition substrate is formed on both the first surface and the second surface, otherwise specified, term “deposition substrate” may refer to the deposition substrate formed on both the first surface and the second surface. So as terms “barrier layer in the deposition substrate”, “support layer in the deposition substrate”, “catalyst layer in the deposition substrate” and “CNT array”.

Optionally, the deposition substrate is formed by sputtering or electron beam deposition. The deposition substrate may also be formed by other method and no limitation is set herein.

In some aspects of the present invention, the barrier layer in the deposition substrate has a melting temperature higher than 2000° C.

In some aspects of the present invention, the barrier layer in the deposition substrate contains at least one material of tantalum (Ta), nitride of tantalum and ruthenium (Ru).

In some aspects of the present invention, a thickness of the barrier layer in the deposition substrate ranges from 5 nm to 50 nm.

In some aspects of the present invention, the support layer in the deposition substrate contains at least one material of titanium nitride (TiN) and titanium-aluminum oxynitride (Ti—Al—O—N).

In some aspects of the present invention, a thickness of the support layer in the deposition substrate ranges from 5 nm to 50 nm.

In some aspects of the present invention, the catalyst layer in the deposition substrate contains at least one material of iron (Fe), cobalt (Co) and nickel (Ni).

In some aspects of the present invention, the carbon nanotube array is synthesized by chemical vapor deposition.

The CVD process may be performed in various conditions according to practical requirements. Generally, the CVD process may be performed in an atmosphere containing C2H2, and the atmosphere may further contain H2. Temperature of the CVD process may be adjusted according to requirements on the CNT array to be synthesized. Generally, denser CNTs may be grown at 600° C. while taller CNTs may be grown at 800° C.; and fairly dense and tall CNTs may be grown at around 700° C. Pressure of the C2H2 may change in accordance with the temperature. For instance, the pressure of C2H2 may be roughly 0.03-0.3 Torr at 600° C., 0.1-1 Torr at 700° C. and 0.3-3 Torr at 800° C., but the present invention does not set limitation to the condition of the CVD process.

Optionally, the chemical vapor deposition is performed in an atmosphere containing C2H2 at a pressure of 0.01-10 Torr, and at a temperature of 600-800° C.

As an alternative, the CVD process may also be performed in an atmosphere of H2 at a partial pressure of 2 Torr and C2H2 at a partial pressure of 0.2 Torr, and at a temperature of around 700° C. In some aspects, the CVD process may be carried out for 20 minutes, but duration of the CVD process may also be other values.

In some aspects of the present invention, a mass density of the carbon nanotube array ranges from 0.1 g/cm3 to 1.5 g/cm3. This is about 10 times higher than that for the conventional case as shown in FIG. 1 (0.01 g/cm3˜0.06 g/cm3).

A CNT in the CNT array may be multi-walled or single-walled, and may have a diameter from 5 nm to 20 nm and a length from 20 μm to 100 μm.

In some aspects of the present invention, before S430, the method 400 further comprises: annealing the metal foil with the deposition substrate formed on the first surface; and accordingly, S430, synthesizing a carbon nanotube array on the deposition substrate formed on the first surface, comprises: synthesizing a carbon nanotube array on the annealed deposition substrate formed on the first surface.

Likely, before S450, the method 400 further comprises: annealing the metal foil with the deposition substrate formed on the second surface; and accordingly, S450, synthesizing a carbon nanotube array on the deposition substrate formed on the second surface, comprises: synthesizing a carbon nanotube array on the annealed deposition substrate formed on the second surface.

In the present invention, annealing of the metal foil with the deposition substrate formed on the first surface and on the second surface may be performed concurrently before S430 and S450, but no limitation is set herein.

Optionally, the annealing is performed in H2 atmosphere and at a temperature of 600-800° C.

The annealing process may be used to reduce catalyst nanoparticles in the catalyst layer that are prone to be oxidized during transferring to the CVD chamber. Condition of the annealing process can be adjusted according to practical requirements. For instance, a relatively lower temperature is suitable to avoid formation of an alloy of the catalyst and the metal foil, while a relatively higher temperature is suitable to reduce the catalyst efficiently. As an example, in the annealing process, the H2 gas may be 100 SCCM (cubic centimeter per minute at STP), and the annealing process may be carried out for 3 minutes, but no limitation is set herein.

In some aspects of the present invention, the method 400 further includes a step of forming an adhesive layer on the carbon nanotube array.

The adhesive layer 240 may be prepared as a metal sheet and has a thickness from 10 μm to 20 μm. Solder may be served as the adhesive layer 240, so as to achieve good contact thermally and electrically.

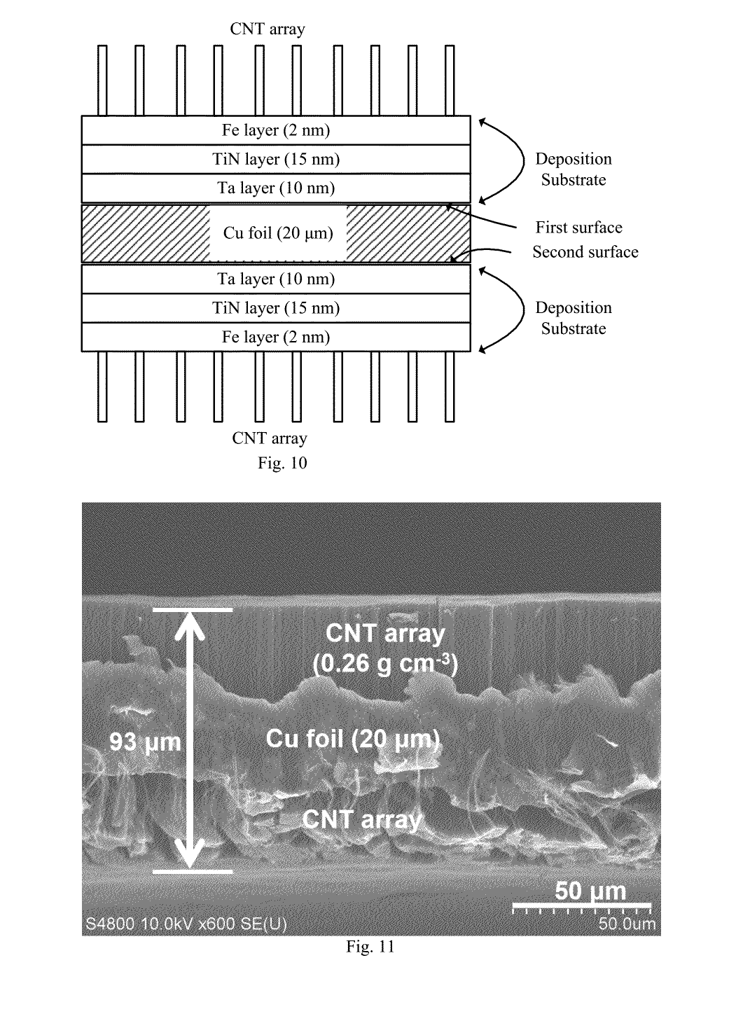

As an example, as shown in FIG. 10, the method 400 is used to synthesize a heat dissipation structure with a nine layer configuration. Firstly, two deposition substrates are deposited on two opposite surfaces of a Cu foil (with a thickness of 20 μm) respectively, wherein each of the two deposition substrates contains a barrier layer composed of Ta (with a thickness of 10 nm), a support layer composed of TiN (with a thickness of 15 nm) that is disposed on the barrier layer, and a catalyst layer composed of Fe (with a thickness of 2 nm) that is disposed on the support layer. Then, CNT arrays are grown on the two deposition substrates by thermal CVD. FIG. 11 displays a cross-sectional scanning electron microscope (SEM) image of an exemplary heat dissipation structure synthesized by the method 400, in which the CNT arrays include multi-wall CNTs having a density of 0.26 g/cm3, and a total height of the heat dissipation structure is around 93 μm.

It should be noted that, the above description on the method 400 is just exemplary rather than limiting the present disclosure. According to practical requirement, a different method can be used to synthesize the CNT array, or at least one parameter of gases, temperature and pressure may be changed in the CVD process. In addition, the heat dissipation structure synthesized by the method 400 may corresponds to the heat dissipation structure 200 depicted by any one of FIG. 2 to FIG. 7, and the description on the heat dissipation structure 200 may be referred to for further information on the heat dissipation structure synthesized by the method 400.

According to the method for synthesizing the heat dissipation structure, a carbon nanotube array is synthesized on a deposition substrate comprising a catalyst layer and a barrier layer, wherein the barrier layer is disposed between the catalyst layer and the metal foil and can prevent catalyst in the catalyst layer from diffusing into the metal foil. Consequently, density of the CNTs in the heat dissipation structure is increased and thermal conductivity of the heat dissipation structure is thus improved.

It should be appreciated that the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concept in a concrete fashion. As used in the present disclosure, the term “and/or” is intended to mean an inclusive “and/or”. That is, unless specified otherwise, or clear from context, “X includes A and/or B” is intended to mean any of natural inclusive permutations, i.e., X may be A, or X may be B, or X may be A and B.

Various embodiments are described in the general context of method steps or processes, which may be implemented in one embodiment by a computer program product, embodied in a computer-readable memory, including computer-executable instructions, such as program code, executed by computers in networked environments. A computer-readable memory may include removable and non-removable storage devices including, but not limited to, read only memory (ROM), random access memory (RAM), compact discs (CDs), digital versatile discs (DVD), etc. Generally, program modules may include routines, programs, objects, components, data structures, etc. that perform particular tasks or implement particular abstract data types. Computer-executable instructions, associated data structures, and program modules represent examples of program code for executing steps of the methods disclosed herein. The particular sequence of such executable instructions or associated data structures represents examples of corresponding acts for implementing the functions describes in such steps or processes. Various embodiments may include a computer-readable medium including computer executable instructions which, when executed by a processor, cause an apparatus to perform the methods and processors described herein.

Embodiments of the present invention may be implemented in software, hardware, application logic or a combination thereof. The software, application logic and/or hardware may reside on a user device, or a controller, such as a content server or a controller. In an exemplary embodiment, the application logic, software or an instruction set is maintained on any one of various conventional computer-readable media. In the context of the present disclosure, the term “computer-readable medium” may be any media or means that can contain, store, communicate, propagate or transport the instructions for use by or in connection with an instruction execution system, apparatus or device, such as a computer.

In the end, it should be noted that the preceding embodiments are merely used to illustrate the technical solutions of the present invention rather than limiting the present disclosure. Though the present disclosure is illustrated in detail by referring to the preceding embodiments, it should be understood by one of skill in the art that modifications may still be made on the technical solutions disclosed in the preceding respective embodiments, or equivalent alterations may be made to a part of technical characteristics thereof and these modifications or alterations do not make the nature of corresponding technical solutions departure from the spirit and scope of the technical solutions of the respective embodiments of the present disclosure.

What is claimed is:

1. A method for synthesizing a heat dissipation structure, comprising:
providing a metal foil;
forming a deposition substrate on a first surface of the metal foil, wherein the deposition substrate comprises a barrier layer disposed on the metal foil and a catalyst layer disposed on the barrier layer, such that catalyst in the catalyst layer is prevented from diffusing into the metal foil; and
synthesizing a carbon nanotube array on the deposition substrate formed on the first surface.

2. The method of claim 1, further comprising:
forming the deposition substrate on a second surface of the metal foil, wherein the second surface is opposite to the first surface of the metal foil; and
synthesizing a carbon nanotube array on the deposition substrate formed on the second surface.

3. The method of claim 1, wherein the deposition substrate further comprises a support layer disposed between the barrier layer and the catalyst layer, such that reactivity of the catalyst in the catalyst layer is improved.

4. The method of claim 1, wherein the deposition substrate is formed by sputtering or electron beam deposition.

5. The method of claim 1, wherein the barrier layer in the deposition substrate has a melting temperature higher than 2000° C.

6. The method of claim 1, wherein the barrier layer in the deposition substrate contains at least one material of tantalum (Ta), nitride of tantalum and ruthenium (Ru).

7. The method of claim 1, wherein a thickness of the barrier layer in the deposition substrate ranges from 5 nm to 50 nm.

8. The method of claim 3, wherein the support layer in the deposition substrate contains at least one material of titanium nitride (TiN) and titanium-aluminum oxynitride (Ti—Al—O—N).

9. The method of claim 3, wherein a thickness of the support layer in the deposition substrate ranges from 5 nm to 50 nm.

10. The method of claim 3, wherein the catalyst layer in the deposition substrate contains at least one material of iron (Fe), cobalt (Co) and nickel (Ni).

11. The method of claim 1, wherein the carbon nanotube array is synthesized by chemical vapor deposition.

12. The method of claim 11, wherein the chemical vapor deposition is performed in an atmosphere containing C₂H₂ at a pressure of 0.01-10 Torr, and at a temperature of 600-800° C.

13. The method of claim 1, wherein a mass density of the carbon nanotube array ranges from 0.1 g/cm³ to 1.5 g/cm³.

14. The method of claim 1, wherein before the synthesizing a carbon nanotube array on the deposition substrate, the method further comprises:
annealing the metal foil with the deposition substrate; and
the synthesizing a carbon nanotube array on the deposition substrate, comprises:
synthesizing a carbon nanotube array on the annealed deposition substrate.

15. The method of claim 1, further comprising:
forming an adhesive layer on the carbon nanotube array.

16. A heat dissipation structure, comprising:
a metal foil;
a deposition substrate disposed on a first surface of the metal foil, wherein the deposition substrate comprises a barrier layer disposed on the metal foil and a catalyst layer disposed on the barrier layer, such that catalyst in the catalyst layer is prevented from diffusing into the metal foil; and
a carbon nanotube array synthesized on the deposition substrate that is disposed on the first surface.

17. The heat dissipation structure of claim 1, further comprising:
the deposition substrate disposed on a second surface of the metal foil, wherein the second surface is opposite to the first surface of the metal foil; and
a carbon nanotube array synthesized on the deposition substrate that is disposed on the second surface.

18. The heat dissipation structure of claim 16, wherein the deposition substrate further comprises a support layer disposed between the barrier layer and the catalyst layer, such that reactivity of the catalyst in the catalyst layer is improved.

19. The heat dissipation structure of claim 16, wherein the barrier layer in the deposition substrate has a melting temperature higher than 2000° C.

20. The heat dissipation structure of claim 16, wherein the barrier layer in the deposition substrate contains at least one material of tantalum (Ta), nitride of tantalum and ruthenium (Ru).

21. The heat dissipation structure of claim 16, wherein a thickness of the barrier layer in the deposition substrate ranges from 5 nm to 50 nm.

22. The heat dissipation structure of claim 18, wherein the support layer in the deposition substrate contains at least one material of titanium nitride (TiN) and titanium-aluminum oxynitride (Ti—Al—O—N).

23. The heat dissipation structure of claim 18, wherein a thickness of the support layer in the deposition substrate ranges from 5 nm to 50 nm.

24. The heat dissipation structure of claim 18, wherein the catalyst layer in the deposition substrate contains at least one material of iron (Fe), cobalt (Co) and nickel (Ni).

25. The heat dissipation structure of claim 16, wherein a mass density of the carbon nanotube array ranges from 0.1 g/cm³ to 1.5 g/cm³.

26. The heat dissipation structure of claim 16, further comprising:
an adhesive layer disposed on the carbon nanotube array.
